(19) United States
(12) Patent Application Publication
(10) Pub. No.: US 2012/0280367 A1
(43) Pub. Date: Nov. 8, 2012

(54) METHOD FOR MANUFACTURING A SEMICONDUCTOR SUBSTRATE

(75) Inventor: Morgane Logiou, St. Martin d'Heres (FR)

(73) Assignee: SOITEC, Bernin (FR)

(21) Appl. No.: 13/464,769

(22) Filed: May 4, 2012

(30) Foreign Application Priority Data
May 5, 2011 (FR) 1154037

(51) Int. Cl. H01L 21/762; H01L 29/06

(52) U.S. Cl. 257/622; 438/458; 257/623; 257/E21.568; 257/E29.022

(57) ABSTRACT

The invention relates to a method for manufacturing a semiconductor substrate by providing a seed support layer and a handle support layer, forming at least one semiconductor layer, in particular of a Group III/V-semiconductor material, over the seed support layer, wherein the at least one semiconductor layer is in a strained state, forming a bonding layer over the at least one semiconductor layer, forming a bonding layer over the handle support layer, and bonding the seed and handle substrates together to obtain a donor-handle compound, by direct bonding between the bonding layer of the seed substrate and the bonding layer of the handle substrate. At least one of the bonding layer of the seed substrate and the bonding layer of the handle substrate includes a silicon nitride.

### BACKGROUND ART

The invention relates to a method for manufacturing a semiconductor substrate.

Complex semiconductor substrates may be manufactured by combining two or more layers. One class of such engineered substrates are semiconductor-on-insulator type substrates, wherein a top semiconductor layer is bonded on a mechanical support layer with a dielectric layer in between. For the top semiconductor layer, a Group III/V semiconductor material such as InGaN (indium gallium nitride) may be used. As a material for the mechanical support, in this case, usually sapphire is employed. Such semiconductor substrates are used in the field of electronics, microelectronics, optoelectronics or photovoltaic.

For manufacturing such semiconductor substrates, for example InGaNOS substrates (i.e., an indium gallium nitride layer bonded on a sapphire mechanical support), a semiconductor layer of a seed substrate is often formed by heteroepitaxy on a seed layer which has a different atomic lattice spacing. That results in a strain present in the semiconductor layer. Thus, in the art, compliant layers such as low-viscosity layers, have been provided between the heteroepitaxial semiconductor layer and a handle substrate to which at least a part the semiconductor layer is transferred, in order to release the strains by heat treatment.

For the transfer to the handle substrate, the so-called Smart Cut™ technique is often employed, wherein a part of the seed substrate is transferred onto the handle substrate. For that purpose, a predetermined weakened plane is formed at a predetermined depth that delimits the layer to be transferred inside the seed substrate by implanting ionic species such as hydrogen and/or helium. After the seed substrate has been bonded to the handle substrate typically using two bonding layers comprising a silicon oxide, a remainder of the seed substrate is detached under thermal treatment, by splitting at the predetermined weakened plane.

A drawback of known manufacturing processes is that the transfer of the semiconductor layers is often incomplete and/or that detects, such as cracks, are formed in the transferred semiconductor layers. The range of size of the defects usually goes from 0.1 μm to a few millimeters. The defects may include non transferred areas (macroscopic and/or microscopic scale), cracks, in particular along the whole thickness of the transferred semiconductor layers, roughness and/or non-uniformity of the transferred semiconductor layers. As a consequence, significant parts of the transferred semiconductor layer cannot be used for further processing; in other words, defects lead to yield loss.

Due to the strain in the InGaN layer, defects, such as cracks, extend to the InGaN layer itself and/or to an additional GaN layer, which is often provided as a seed layer below the InGaN layer.

In order to solve this issue, several approaches have been proposed, which mainly aim at improving the individual processing steps, such as cleaning, polishing etc. Furthermore, the thickness of the transferred semiconductor layer could be decreased to prevent the appearance of cracks in the InGaN layer structure transferred, for example, by reducing the ion implantation energy when forming the predetermined weakened plane from 120 keV to 80 keV. In this way, however, the number of defects may even increase if the predetermined weakened plane gets close to the GaN—InGaN layer interface. Additionally, to avoid buckling of the InGaN layer during a later relaxation step, a controlled thickness for the GaN layer is required.

The present invention now seeks to overcome these disadvantages.

### SUMMARY OF THE INVENTION

The present invention now provides an improved method for fabricating a semiconductor substrate using a layer transfer technique while reducing the number of defects in the transferred semiconductor layer. This method comprises:

providing a seed support layer and a handle support layer;

providing a strained semiconductor layer over the seed support layer;

providing a bonding layer upon the strained semiconductor layer;

providing a bonding layer upon the handle support layer; and

directly bonding the bonding layers together to obtain a donor-handle compound comprising the seed support layer bonded to the handle support layer. Advantageously, one of the bonding layers comprises a silicon nitride in order to enhance bonding strength between the seed support layer and the handle support layer, while the other one of the bonding layers generally comprises a silicon oxide.

It has been discovered that using one bonding layer comprising a silicon nitride increases the bonding energy between the two bonding layers compared to the bonding energy between two bonding layers comprising only silicon oxide layers, as used in the state of the art. In this way, particularly the bonding energy can be increased with regard to the splitting interface energy and the defects in the transferred semiconductor layer may be significantly decreased.

Preferably, the bonding layer comprising a silicon nitride comprises or consists of SiN material or SiₓN_{y}:H (x+y=1) and wherein the bonding layer comprising silicon oxide comprises or consists of borophosphosilicate glass or plasma enhanced chemical vapor deposition oxide.

The method further comprises providing a low viscosity compliant layer upon the seed support layer or handle support layer before providing the bonding layer comprising a silicon nitride thereon. Also, the bonding layer comprising silicon nitride or the compliant layer can be subjected to a thermal treatment before the bonding step to further enhance bonding energy.

The invention also relates to a donor-handle compound comprising:

a seed substrate comprising a seed support layer, a strained semiconductor layer upon the seed support layer, and a first bonding layer, the seed substrate including a weakened plane therein; and

a handle substrate comprising a handle support layer and a second bonding layer.

A direct bonding is provided between the first and second bonding layers, such as by molecular bonding of polished bonding layers, and one of the first or second bonding layers comprises a silicon nitride while the other one of the first or second bonding layers comprises or consists of a silicon oxide.

Yet another embodiment of the present invention relates to a layered structure comprising a handle support layer and a strained material layer; wherein the strained material layer is bonded to the handle support layer via a first bonding layer comprising a silicon nitride and a second bonding layer comprising a silicon oxide. The trenches are present in at least the strained material layer and optionally but preferably also in the first bonding layer, the second bonding layer, or both bonding layers. If desired, an absorbing layer can be provided between the handle support layer and the first and second bonding layers.

### BRIEF DESCRIPTION OF THE DRAWINGS

Advantageous embodiments will be described in combination with the enclosed figures.

FIGS. 1a-1c illustrate different steps of an exemplary method for manufacturing a semiconductor substrate according to the invention;

FIGS. 2a-2d illustrate a seed substrate at different steps of an exemplary method for manufacturing a semiconductor substrate according to the invention;

FIGS. 3a-3c illustrate a handle substrate at different steps of an exemplary method for manufacturing a semiconductor substrate according to the invention;

FIG. 4 illustrates an exemplary donor-handle compound according to the invention;

FIG. 5 illustrates an exemplary seed substrate and another exemplary handle substrate according to the invention;

FIG. 6 illustrates a further exemplary seed substrate and handle substrate according to the invention;

FIG. 7 illustrates a further exemplary seed substrate and handle substrate according to the invention;

FIG. 8 illustrates exemplary layered structures after detaching a remainder of the seed substrate according to the invention;

FIGS. 9a-9b illustrate further exemplary process steps for manufacturing a semiconductor substrate according to the invention;

FIG. 10 shows a diagram illustrating the bonding energy between exemplary bonding layers according to the invention compared to the bonding energy between exemplary bonding layers according to the state of the art.

### DETAILED DESCRIPTION OF THE INVENTION

In particular, the invention relates to a method for fabricating a semiconductor substrate using a layer transfer technique while increasing the bonding strength in the substrate while also reducing the number of defects in the transferred semiconductor layer.

This method advantageously comprises:

providing a seed support layer and a handle support layer,

forming a semiconductor layer, in particular comprising a Group semiconductor material, over the seed support layer, wherein the semiconductor layer is in a strained state,

forming a bonding layer over the semiconductor layer,

forming a bonding layer over the handle support layer, and

bonding a thus obtained seed substrate to a thus obtained handle substrate to obtain a donor-handle compound, resulting from a direct bonding between the bonding layer of the seed substrate and the bonding layer of the handle substrate,

wherein one of the bonding layer of the seed substrate and the bonding layer of the handle substrate comprises a silicon nitride.

The inventive method may particularly be used for manufacturing a semiconductor on insulator, wherein a semiconductor layer is bonded over a support layer with an insulating layer in between. Generally, the method relates to substrates but is also applicable to layers that are combined to form such substrates.

As used herein, therefore, the term “substrate” refers to a layered structure comprising one or more layers or films.

In particular, the term “seed substrate” refers to a layered structure comprising one or more layers or films over a seed support layer. Accordingly, the term “handle substrate” refers to a layered structure comprising one or more layers or films over a handle support layer.

The term “direct bonding” refers to a bonding based on molecular adhesion and is particularly to be distinguished from a bonding using an adhesive. In other words, the bonding layer of the seed substrate and the bonding layer of the handle substrate are properly prepared so that they adhere to each other thanks to molecular adhesion.

The donor-handle compound, thus, can be obtained by a direct bonding between the bonding layer of the seed substrate and the bonding layer of the handle substrate.

The semiconductor layer being in a strained state means that the lattice parameter of the material is different from its nominal lattice parameter taking into account measurement uncertainty. This strain may be a tensively or a compressively strain.

The above mentioned method steps may particularly be performed in this order. In other words, the method steps may be performed, subsequently.

According to an advantageous realization, the other one of the bonding layer of the seed substrate and the bonding layer of the handle substrate may comprise a silicon oxide. In other words, a direct bonding may be performed between a bonding layer comprising a silicon nitride and a bonding layer comprising a silicon oxide. In this way, the bonding energy between the two bonding layers may be advantageously increased.

In particular, the bonding layer of the seed substrate may comprise or consist of a silicon nitride and the bonding layer of the handle substrate may comprise or consist of a silicon oxide or the bonding layer of the handle substrate may comprise or consist of a silicon nitride and the bonding layer of the seed substrate may comprise or consist of a silicon oxide.

If the bonding layer of the handle substrate comprises or consists of a silicon nitride its thickness can be reduced. This can improve the relaxation comparing to the case of realization with silicon nitride on the seed substrate.

The semiconductor layer may comprise or consist of a Group III/V semiconductor material, in particular a Group III-N (Nitride) material, for example a binary, quaternary or ternary nitride. For example, the semiconductor layer may comprise or consist of indium gallium nitride (InGaN) and/or gallium nitride (GaN) and/or aluminum gallium nitride (AlGaN).

The semiconductor layer may be deposited or formed by epitaxy, in particular pseudomorphic epitaxy, on a seed layer formed over the seed support layer.

As the seed layer formed between the seed support layer and the semiconductor layer may have an atomic lattice spacing which does not match the atomic lattice spacing of the semiconductor, the semiconductor layer can be in a strained state.

The semiconductor layer may particularly comprise or consist of indium gallium nitride (InGaN) and/or the seed layer may comprise or consist of gallium nitride (GaN).

The handle support layer may particularly comprise or consist of sapphire and/or glass and/or quartz and/or silicon (Si). The seed support layer, for growth of Group III/V semiconductor materials, may particularly comprise or consist of sapphire, or Si.

The bonding layer comprising a silicon nitride may comprise or consist of SiN material such as Si3N4 and/or SixNy:H and/or the bonding layer comprising a silicon oxide may comprise or consist of BPSG (borophosphosilicate glass) and/or PECVD (plasma enhanced chemical vapor deposition) oxide.

SiₓN_{y}H_{z}, (x+y+z=1), for example, is a SiN material which may be used for the bonding layer comprising a silicon nitride. It is formed by PECVD at rather low temperature. This particular material is non stochiometric and non homogenous, and can be particularly suited as a bonding layer thanks to its low density. It can provide a means to incorporate into its thickness the bonding by-product (gas, water molecules, . . . ) and prevent from their accumulation at the bonding interface in the form of blisters.

The bonding layer of the seed substrate may comprise a silicon nitride and a compliant layer such as a low-viscosity layer, for example comprising BPSG, may be formed between the semiconductor layer and the bonding layer of the seed substrate. The layer such as the low-viscosity layer may be used for relaxation of the strained semiconductor layer.

Alternatively, the bonding layer of the handle substrate may comprise a silicon nitride and a compliant layer such as a low-viscosity layer, for example comprising BPSG, may be formed between the handle support layer and the bonding layer of the handle substrate. The layer such as the low-viscosity layer may be similarly used for relaxation of the strained semiconductor layer.

Alternatively or additionally the bonding layer comprising or consisting of a silicon oxide, in particular BPSG, may be used for relaxing the strained semiconductor layer.

The bonding layer comprising a silicon nitride may be formed by PECVD or by a low pressure chemical vapor deposition (LPCVD). A layer formed by chemical vapor deposition reproduces the topology of the surface of the layer on which the layer is formed.

The bonding layer comprising a silicon nitride may be formed by plasma enhanced chemical vapor deposition (PECVD) using the precursors SiH₄ and NH₃.

According to an advantageous realization, the method may further comprise the densification of the bonding layer of the seed substrate and/or the bonding layer of the handle substrate, in particular wherein the densifying step comprises a heat treatment. In particular, it has been found that, if the bonding layers are not densified, small gas bubbles may form, and may accumulate at the bonding interface between the two layers. As a consequence, de-bonding may occur before splitting at the predetermined weakened plane.

The bonding layer comprising silicon nitride and/or the compliant layer such as a BPSG layer, thus, may be subject to a thermal treatment before the bonding step. In this way, a degassing of these layers may be achieved.

This densifying step may be performed at a temperature higher than the temperature used when forming the bonding layer of the seed substrate and/or the bonding layer of the handle substrate. In this way, the gas contained in the bonding layer of the seed substrate and/or the bonding layer of the handle substrate during and/or after formation can be desorbed.

Further preferred, the densifying step may be performed at a temperature which is higher than any temperature used in subsequent process steps. In this way, the desorption of the bonding layer of the seed substrate and/or the bonding layer of the handle substrate can be optimized.

The densifying step may be particularly performed at a temperature above 800° C. In particular, during a subsequent relaxation of the semiconductor layer, the bonding layers may be subjected to a treatment at 800° C.

In particular, the densifying of the bonding layer comprising a nitride may be performed using nitrogen and/or the densifying of the bonding layer comprising an oxide may be performed using oxygen.

According to a preferred embodiment, the handle support layer may comprise or consist of sapphire and the method may further comprise forming an absorbing layer, in particular silicon nitride, between the handle support layer and the bonding layer of the handle substrate which particularly consist of silicon dioxide. In this way, the handle support layer may be advantageously removed by a laser lift off technique in subsequent process steps. In particular, the absorbing layer may be formed such as to absorb the laser light used for the laser lift off of the handle support layer.

The absorbing layer, particularly comprising a nitride, between the handle support layer and the bonding layer may particularly comprise or consist of a silicon nitride. Between the absorbing layer and the handle support layer, additionally, a layer comprising an oxide, in particular comprising or consisting of a silicon oxide, may be formed.

According to an advantageous realization, the method may further comprise processing, in particular polishing, the bonding layer of the seed substrate such that its surface roughness is less than 5 Angstroms (Å), in particular less than or equal to around 2 Å and/or processing, in particular polishing, the bonding layer of the handle substrate such that its surface roughness is less than 5 Å, in particular less than or equal to around 2 Å, before the bonding step. In this way, the direct bonding between the two bonding layers may be improved. The bonding layer of the seed substrate and/or the bonding layer of the handle substrate may be particularly processed such that their roughness is less than or equal to 2 Å before the bonding step.

According to a preferred embodiment, the method may further comprise forming a predetermined weakened plane at a depth h inside the seed substrate.

The weakened plane may particularly be formed inside the seed layer on which the semiconductor layer is formed by epitaxy.

Forming the predetermined weakened plane may comprise an ion implantation step. The depth h of the predetermined weakened plane may be determined by the energy of the implanted ionic species. The implanted ionic species for forming the predetermined weakened plane may be or may comprise hydrogen. It may also be or comprise rare gas ions (helium, argon etc.).

Thus, ionic species may be implanted through the semiconductor layer to form a weakened plane at a depth h inside the seed substrate.

The step of forming a predetermined weakened plane may particularly be performed after the step of forming the at least one bonding layer comprising a silicon nitride, in particular after the densifying step. Otherwise, the temperatures used for forming and/or densifying the bonding layer may induce the formation of bubbles in the predetermined weakened plane, which would have a negative influence on the splitting quality.

Further preferred, the method may comprise separating a remainder of the seed substrate from the donor-handle compound, wherein separation occurs at the predetermined weakened plane, thereby forming a transferred semiconductor layer over the handle substrate. In other words, at least a part of the semiconductor layer may be transferred from the seed substrate onto the handle substrate.

In particular, the inventive method may further comprise an annealing of the donor-handle compound. The annealing may strengthen the direct bonding between the two bonding layers and may finally lead to the separation at the predetermined weakened plane.

If the predetermined weakened plane is formed inside the seed layer of the seed substrate, by separating a remainder of the seed substrate from the donor-handle compound a transferred seed layer may be formed. In other words, at least a part of the seed layer on which the semiconductor layer was formed may be transferred from the seed substrate onto the handle substrate.

Thus, at least a part of the seed layer may be transferred to the handle substrate, thereby forming a transferred seed layer over the transferred semiconductor layer.

Prior to bonding the seed substrate to the handle substrate, the handle and/or the seed substrate, in particular the bonding layers of the handle and/or the seed substrate, may be prepared for bonding, e.g. by cleaning, or any suitable surface treatments.

Advantageously, the method may further comprise forming trenches in the transferred semiconductor layer, in particular such that an island shaped structure is obtained in the transferred semiconductor layer. The trenches may also extend into the bonding layer of the seed substrate and/or the bonding layer of the handle substrate.

The trenches may be formed at least partly in a compliant layer such as a low-viscosity layer formed between the transferred semiconductor layer and the handle support layer. The low-viscosity layer may particularly comprise or consist of BPSG.

The method may further comprise an at least partial relaxation of the transferred semiconductor layer by a heat treatment, in particular, wherein at least one of the bonding layers comprises a BPSG layer. A transferred seed layer may be used as a stiffener for at least partially relaxing the transferred semiconductor layer.

The transferred semiconductor layer over the handle substrate, in particular over the handle support layer, may be subsequently bonded to a target substrate. The target substrate may comprise one or more layers or films over a target support layer. The target substrate may also correspond to the target support layer.

The target support layer may particularly comprise or consist of sapphire and/or glass and/or quartz.

The method may particularly comprise forming an oxide layer, in particular a silicon oxide layer, over the transferred semiconductor layer and/or in the trenches and attaching, in particular by direct bonding, the oxide layer to the target substrate. In this way, a transfer of the transferred semiconductor layer to a target substrate may be achieved.

The method may further comprise detaching the handle support layer, in particular by laser lift off. In this way, an intermediate layered structure may be obtained, wherein the intermediate layered structure comprises at least the target substrate and the transferred semiconductor layer with the oxide layer, in particular the silicon oxide layer, formed in between.

The method may further comprise processing the intermediate layered structure by chemical mechanical polishing and/or by etching such that layers arranged over and/or between the transferred semiconductor layer, in particular between different areas or islands of the island shaped transferred semiconductor layer, are removed, thereby obtaining a final layered structure comprising the target substrate, the oxide layer formed over the target substrate and the transferred semiconductor layer, in particular the island shaped transferred semiconductor layer, formed over the oxide layer. In this way, the final semiconductor substrate, in particular the final semiconductor on insulator substrate, can be obtained.

The invention further provides a donor-handle compound comprising:

a seed substrate and a handle substrate,

wherein the seed substrate comprises a seed support layer, a semiconductor layer, in particular comprising a Group III/V-semiconductor material, over the seed support layer, wherein the semiconductor layer is in a strained state, and

a first bonding layer,

wherein a weakened plane is formed in the seed substrate, and

wherein the handle substrate comprises a handle support layer, and a second bonding layer, wherein a direct bonding is formed between the first bonding layer and the second bonding layer, and wherein one of the first and the second bonding layer comprises a silicon nitride.

The donor-handle compound may particularly be formed using a method as discussed above. Advantageously, the semiconductor layer, the first bonding layer and the second bonding layer may comprise one or more of the above-described features.

In particular either the first bonding layer or the second bonding layer may comprise or consist of a silicon oxide.

The invention further provides a layered structure comprising:

a handle support layer, and

a strained material layer,

wherein the strained material layer is bonded to the handle support layer via a first bonding layer comprising a silicon nitride and a second bonding layer comprising a silicon oxide. The layered structure may particularly be formed using a method as discussed above.

Advantageously, the handle support layer, the first bonding layer and the second bonding layer may comprise one or more of the above-described features. The strained material layer may particularly correspond to a semiconductor layer in a strained state. The semiconductor layer may comprise one or more of the above-described features. The strained material layer may particularly correspond to the above described transferred semiconductor layer.

According to a preferred embodiment, trenches may be formed in the strained material layer and/or in the first bonding layer and/or in the second bonding layer.

The layered structure may further comprise an absorbing layer, in particular from silicon nitride, formed between the handle support layer and the first and second bonding layers. The absorbing layer may be used for a laser lift off technique of the handle support layer as described above. The absorbing layer may comprise one or more of the above-described features.

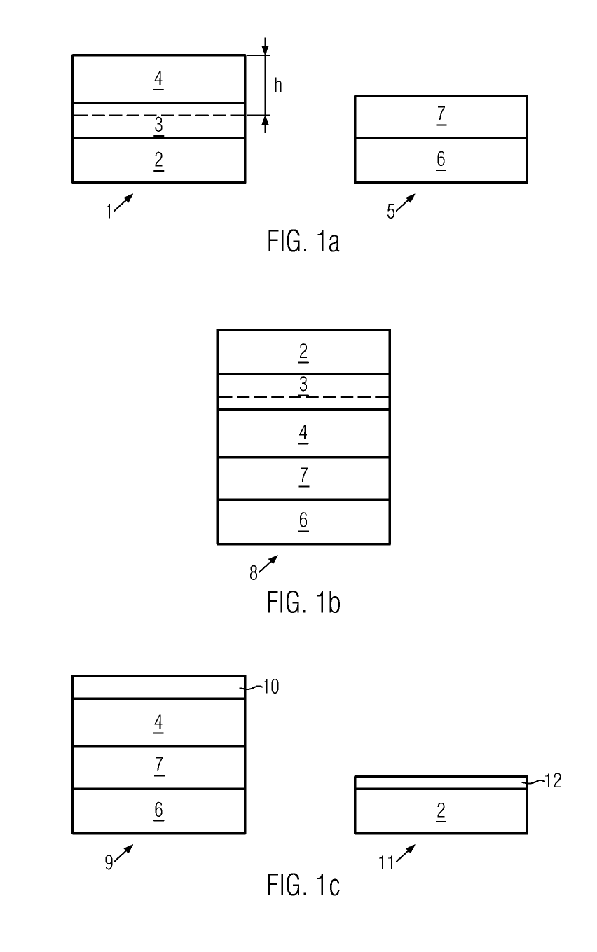

In FIGS. 1a-1c, process steps according to an exemplary method for manufacturing a semiconductor substrate according to the invention are shown.

In FIG. 1a, a seed substrate 1 and a handle substrate 5 are provided. The seed substrate 1 comprises a seed support layer 2 and a semiconductor layer 3 is formed over the seed support layer 2. Over the semiconductor layer 3, a bonding layer 4 is formed. A predetermined weakened plane at a depth h is formed inside the semiconductor layer 3, which is illustrated as a dashed line in FIG. 1a. The predetermined weakened plane is preferably formed using an ion implantation process after forming the bonding layer 4.

The handle substrate 5 comprises a handle support layer 6 and a bonding layer 7 formed over the handle support layer 6. The seed support layer 2 and/or the handle support layer 6 may comprise or consist of silicon or sapphire. The semiconductor layer 3 may particularly comprise a Group III/V semiconductor material, such as indium gallium nitride (InGaN).

The semiconductor layer 3 may be formed by epitaxy, in particular pseudomorphic epitaxy, on a seed layer (not shown) formed over the seed support layer 2. The seed layer formed between the seed support layer 2 and the semiconductor layer 3 may have an atomic lattice spacing which does not match the atomic lattice spacing of the semiconductor layer 3, and, as a consequence the semiconductor layer 3 can be in a strained state. The seed layer can be of GaN.

One of the bonding layer 4 of the seed substrate 1 or the bonding layer 7 of the handle substrate 5 may comprise a silicon nitride. The other one of the bonding layer 4 of the seed substrate 1 and the bonding layer 7 of the handle substrate 5 may comprise a silicon oxide, such as BPSG.

In FIG. 1b, a donor-handle compound 8 is shown, obtained by bonding the seed substrate 1 to the handle substrate 5 such that a direct bonding is formed between the bonding layer 4 of the seed substrate 1 and the bonding layer 7 of the handle substrate 5. Typically, the bonding I molecular bonding of suitably prepared cleaned and polished) substrate surfaces.

By tempering the donor-handle compound 8 using predetermined temperatures, the transfer of part of the seed layer can be made to the handle substrate by separating a remainder of the seed substrate 1 from the donor-handle compound 8, wherein separation occurs at the predetermined weakened plane. In this way, a first layered structure 9 and a second layered structure 11 as shown in FIG. 1c are obtained, wherein the first layered structure 9 comprises the handle support layer 6, the bonding layer 7 of the handle substrate 5, the bonding layer 4 of the seed substrate 1 and a transferred semiconductor layer 10, which comprises at least a part of the semiconductor layer 3. The second layered structure 11 comprises the seed support layer 2 and possibly a remainder 12 of the semiconductor layer 3.

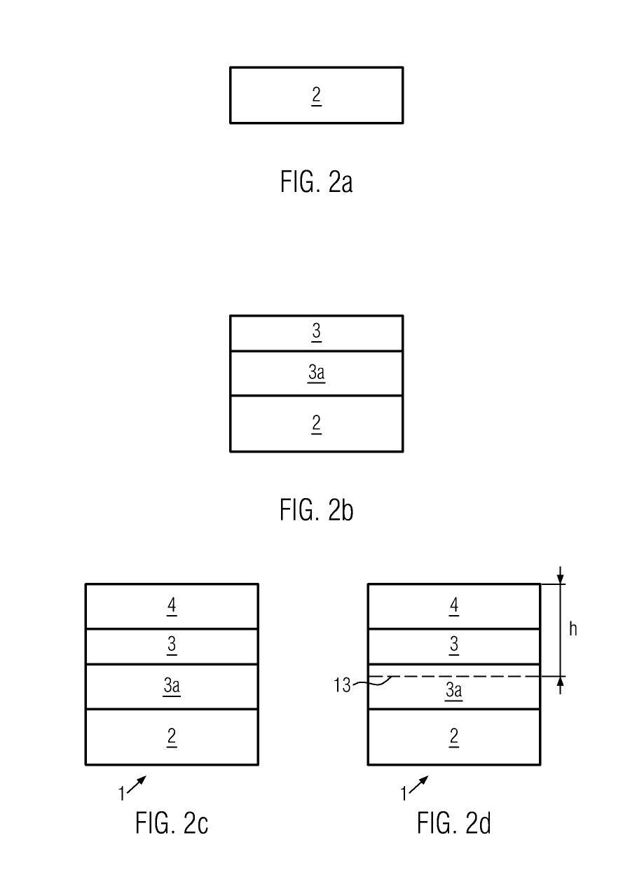

In FIGS. 2a-2d, a seed substrate at different steps of an exemplary method for manufacturing a semiconductor substrate according to the invention is shown. First, a seed support layer 2 is provided in FIG. 2a. The exemplary seed support layer 2 consists of sapphire in this example, but a skilled artisan is aware of other, different materials that may be used for the seed support layer 2, such as silicon.

Over the seed support layer 2, a seed layer 3a is formed typically comprising GaN (gallium nitride). In this example, the seed layer 3a has a thickness of 3 μm. Over the seed layer 3a, a semiconductor layer 3 is formed, typically comprising indium gallium nitride, by epitaxy. In this example, the semiconductor layer 3 has a thickness of 150 nm. This structure is illustrated in FIG. 2b. Due to the non-matching atomic lattice spacings of the seed layer 3a and the semiconductor layer 3, the semiconductor layer 3 is in a strained state.

Over the semiconductor layer 3, a bonding layer 4 comprising a silicon nitride is formed. In this example, the bonding layer 4 consists of silicon nitride and has a thickness of 550 nm. The bonding layer 4, according to this example, is a SiₓN_{y}H_{z} nitride formed using a PECVD method. Alternatively, the bonding layer 4 may also be formed using an LPCVD method. The accordingly obtained exemplary seed substrate 1 is shown in FIG. 2c.

The bonding layer 4 of the seed substrate 1 is densified using nitrogen, according to this example, for one hour at a temperature of 850° C. The densifying step may be particularly performed at a temperature which is higher than the temperature for forming the bonding layer 4 using the PECVD technique and higher than the temperature used in any of the subsequent process steps. Generally, this densifying step is conducted at temperatures of 750° C. to 1000° C. from 30 minutes to 2 hours.

Next, hydrogen ions are implanted at a predetermined depth h inside the seed layer 3a through the bonding layer 4 and the semiconductor layer 3, in order to form a predetermined weakened plane 13. In this example, the depth h is measured in the direction of ion implantation, from the surface of the bonding layer 4 of the seed substrate. For instance, the energy for the ion implantation step may be above 160 keV with a dose above 1.3×10¹⁷ cm⁻², for a splitting temperature of approximately 400° C. The energy for the ion implantation step particularly depends on the desired thickness for the transferred semiconductor layer. A seed substrate 1 having a predetermined weakened plane 13 at a predetermined depth h inside the seed layer 3a is shown in FIG. 2d.

In order to prepare the seed substrate 1 for bonding, a chemical mechanical polishing may be performed. A fraction of the bonding layer 4 having three times the thickness of the peak to valley (PV) amplitude of the surface topology of the layer on which the bonding layer 4 has been formed may be removed by polishing from the bonding layer 4. For instance, if the peak to valley amplitude of the topology of the surface of the indium gallium nitride layer 3 is 50 nm, the peak to valley amplitude of the bonding layer 4 is at least 50 nm due to the PECVD method, which reproduces the topology of the surface of the layer on which the layer is formed. Hence, as a first approximation, 3×50=150 nm of the bonding layer 4 has to be polished, in particular removed, to planarize the surface of the bonding layer 4 in order to make it ready for bonding.

After polishing, the thickness of the bonding layer 4 should be at least 50 μM to 100 nm in order to encapsulate the topology of the semiconductor layer 3. Hence, according to this example, the initial thickness of the bonding layer 4 formed over the semiconductor layer 3 should be at least 150+100=250 nm. After the formation of the predetermined weakened plane, according to this example, 400 nm of the bonding layer 4 may be removed using chemical mechanical polishing. In this way, the bonding layer 4 having a remaining thickness of 150 nm may be provided with a roughness of approximately 2 Å.

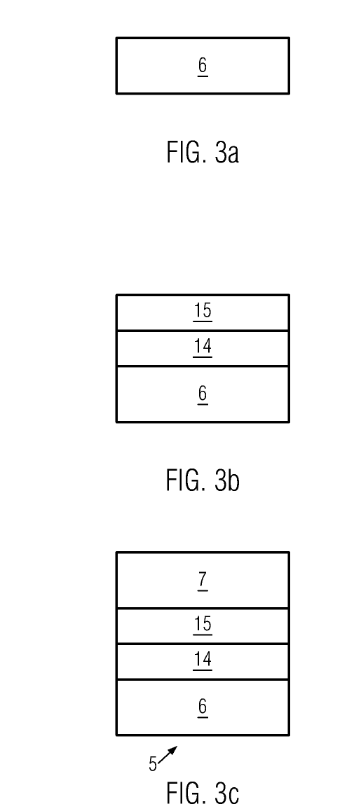

In FIGS. 3a-3c, a handle substrate at different steps of an exemplary method for manufacturing a semiconductor substrate according to the invention is shown. First, a handle support layer 6 consisting of sapphire is provided in FIG. 3a. Also the handle support layer 6 may, as a variant, comprise or consist of a different material, such as silicon, glass or quartz.

A silicon dioxide layer 14 having a thickness of 200 nm and a silicon nitride layer 15 having a thickness of 200 nm are deposited over the handle support layer 6. The silicon nitride layer 15 acts as an absorbing layer. The buried silicon dioxide layer 14 and the buried silicon nitride layer 15 will allow a laser lift off of the handle support layer 6 without damaging the handle support layer 6 as a subsequent process step described further herein. FIG. 3b shows such a handle support layer 6 with a SiO₂ layer 14 and a silicon nitride layer 15.

FIG. 3c shows a handle substrate 5, wherein a bonding layer 7 is formed over the silicon nitride layer 15. In this case, the bonding layer 7 consists of borophosphosilicate glass (BPSG) and has a thickness of 1 μm. A preferred bonding layer 7 composition may comprise 43% boron and 1.45% phosphorus.

In a subsequent process step, the bonding layer 7 is densified using oxygen, in this example, at a temperature of 850° C. for one hour. In this way a densified BPSG layer (BPSGd) may be obtained. The bonding layer 7 may alternatively be formed of a different material, such as silicon dioxide. Advantageously, the bonding layer 7 is formed of a material having a low viscosity, such as BPSG in this example, suitable for relaxing the strained material which forms the semiconductor layer of the seed substrate, in this example the InGaN layer 3 of the seed substrate 1.

In a subsequent process step, the bonding layer 7 is polished using chemical mechanical polishing, wherein approximately 200 nm of the bonding layer are removed, thereby obtaining a roughness of the bonding layer 7 of approximately 2 Å, which allows a direct bonding with the bonding layer 4 of the seed substrate 1.

Subsequently, the handle substrate 5 may be bonded with the seed substrate 1 as discussed above, thereby obtaining a donor-handle compound.

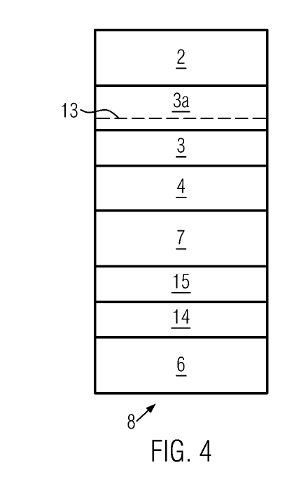

An exemplary donor-handle compound 8 according to the invention is shown in FIG. 4. In particular, the donor-handle compound 8 of FIG. 4 comprises a handle support layer 6, a silicon dioxide layer 14, a silicon nitride layer 15, a bonding layer 7 comprising a silicon oxide, a bonding layer 4 comprising a silicon nitride, a semiconductor layer 3, a seed layer 3a with a predetermined weakened plane 13 formed therein and a seed support layer 2. This donor-handle compound 8 is then annealed in an oven using one or more predetermined temperatures and/or temperature gradients that are generally known in the art. In this way, firstly, the bonding energy at the interface between the bonding layer 4 and the bonding layer 7 is increased. Secondly, at a predetermined splitting temperature, separation occurs at the predetermined weakened plane 13 either naturally or with the addition of external mechanical forces.

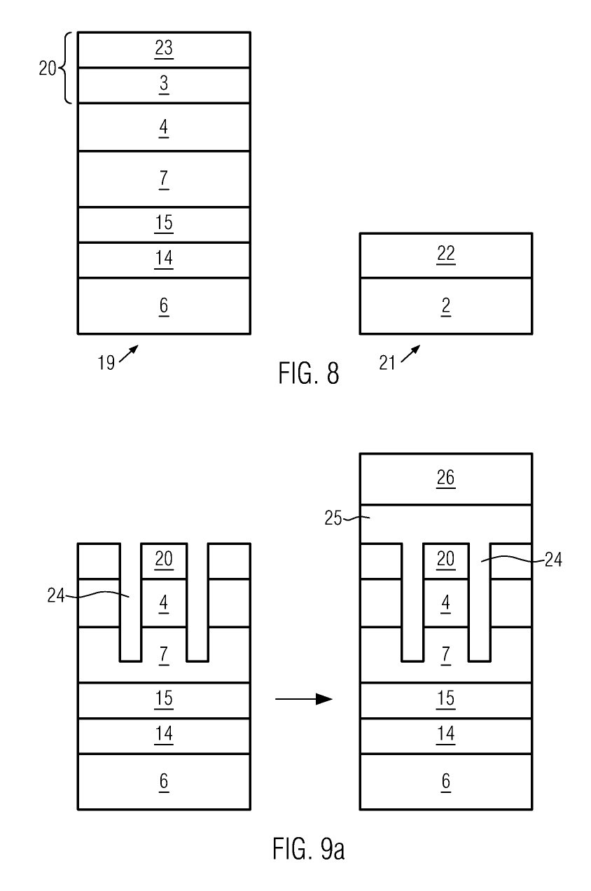

A thus obtained first layered structure 19 comprising a transferred layer 20, which comprises the semiconductor layer 3 and a transferred part 23 of the seed layer 3a as well as a second layered structure 21 comprising a remaining seed layer 22, coming from the initial seed layer 3a, over the seed support layer 2 are shown in FIG. 8.

In the above-described example, the bonding layer comprising a silicon nitride has been formed over the semiconductor layer 3 of the seed substrate 1 and the bonding layer comprising a silicon oxide has been formed over the silicon nitride layer 15 of the handle substrate 5. However, also different arrangements of the bonding layers are possible.

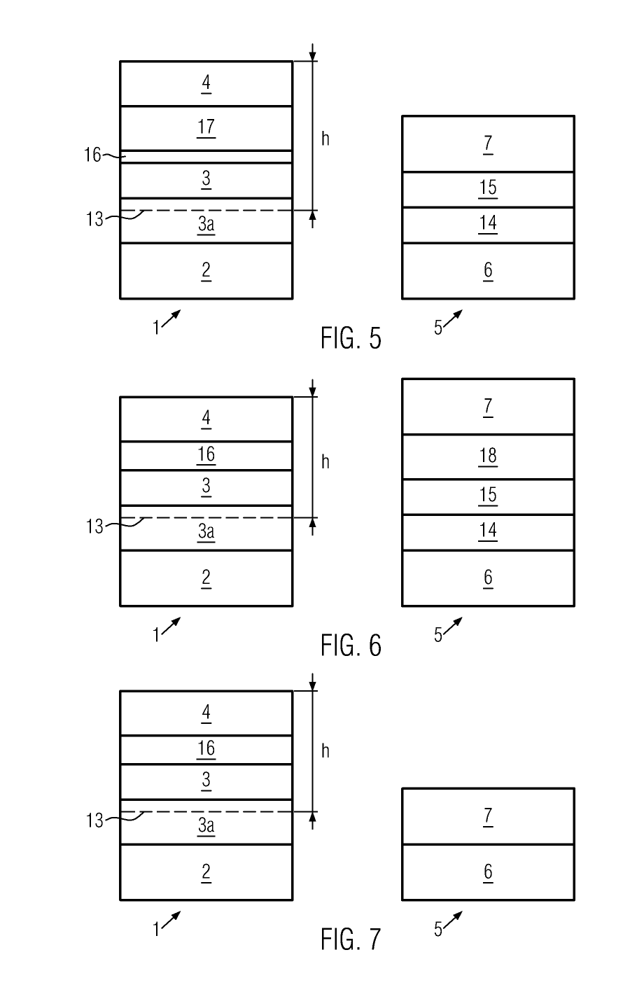

For instance, FIG. 5 shows a variant wherein the bonding layer 4 comprising a silicon nitride is formed over a compliant layer such as a low-viscosity layer 17, in particular comprising a silicon oxide, and preferably BPSG. The low-viscosity layer 17 is formed over the semiconductor layer 3 with a silicon dioxide layer 16 formed in between. In this case, the thickness of the bonding layer 4 and/or of the low-viscosity layer 17 and/or of the silicon dioxide layer 16 may be chosen such that the predetermined depth h of the predetermined weakened plane can be achieved by the ionic implantation.

The low-viscosity layer 17 may be composed of different individual sub-layers and may comprise at least a compliant material sub-layer (relaxing sub-layer). A compliant material is a material that shows some reflow (e.g., due to some glass transition) at a temperature above the glass transition temperature reached by heat treatment. The reflow (melting flow) results in an elastic strain relaxation of the strained semiconductor layer 3 on that the low-viscosity layer, e.g., the above-mentioned buried (oxide) layer, is deposited. Suitable compliant materials include borophosphosilicate glass (BPSG) or a SiO₂ compound comprising B (BSG) or P (PSG), for example. The glass transition temperature of a low-viscosity BPSG layer that includes 4.5% of boron (B) and 2% of phosphorous (P) is about 800° C. Most of low viscosity oxide materials have a glass transition temperature around 600-700° C. whereas the glass transition temperature of the high-viscosity oxide material is above 1000° C. and preferably above 1200° C.

The handle substrate 5 corresponds to the handle substrate 5 shown in FIG. 3c.

In the examples shown in FIGS. 1-4, the bonding layer 7 of the handle substrate may have, additionally to bonding, the same function as the low-viscosity layer 17 for at least partially relaxing the semiconductor layer 3, in particular the transferred semiconductor layer, which is initially present in a strained state.

According to a further alternative shown in FIG. 6, the bonding layer 7 of the handle substrate 5 may comprise or consist of a silicon nitride. In this case, the bonding layer 7 may be formed over the silicon nitride layer 15 with a silicon oxide layer 18, particularly a BPSG layer, formed in between. In this example, the bonding layer 4 of the seed substrate 1 may comprise a silicon oxide. In particular, the bonding layer 4 may consist of BPSG and may be formed over the semiconductor film 3 with a silicon dioxide layer 16 formed in between. In this case, the bonding layer 4 of the seed substrate 1, additionally to bonding, and the layer 18 of the handle substrate may have the same function as the low viscosity layer 17 described above for at least partially relaxing the semiconductor layer 3, in particular the transferred semiconductor layer, which is initially present in a strained state.

The silicon oxide layer 18 may be polished before forming the bonding layer 7 of silicon nitride. Consequently, the bonding layer 7 would have a roughness suitable for bonding directly after its formation.

In this case, the thickness of the bonding layer 7 may be 50 nm or less, in particular, 20 nm or less. As this thickness is smaller compared to the thickness of the bonding layer 4 described above with reference to FIGS. 2a-2d, a negative influence of the bonding layer comprising a silicon nitride on the relaxation of the semiconductor film 3, in particular the transferred semiconductor film, may be reduced. Furthermore, the preparation of the surface of the bonding layer 7 may be faster compared to the above described embodiments as it only aims at activating the surface, not at a topological removal of parts of the layer.

According to a third alternative shown in FIG. 7, the bonding layer 7 of the handle substrate 5 may comprise or consist of a silicon nitride and be formed directly over, in particular on, the handle support layer 6. The seed substrate 1, according to this example, may correspond to the seed substrate 1 described with regard to FIG. 6. In this case, the thickness of the bonding layer 4 comprising BPSG may be chosen such as to allow for a relaxation of the semiconductor layer while obtaining a sufficient implantation depth to form the predetermined weakened plane 13.

By using a bonding layer comprising a silicon nitride for the handle substrate or the seed substrate, the bonding energy between the bonding layers may be enhanced compared to the bonding energy between two bonding layers comprising a silicon oxide, as used in prior art methods. Particularly the bonding energy may be increased with regard to the splitting interface energy which results in a reduced number of defects in the transferred semiconductor layer.

FIG. 10 shows a diagram illustrating the bonding energy between exemplary bonding layers according to the invention, i.e. a silicon nitride layer and a BPSG layer designated as BPSGd layer (right hand side column), compared to the bonding energy between exemplary bonding layers according to the state of the art, i.e., two BPSG layers designated as BPSGd layers (left hand side column). This particular bonding study as been performed without any implantation step, only for the purpose of measuring bonding energies of various configuration. As it can be seen from the diagram, the bonding energy can be significantly increased using a silicon nitride layer and a BPSGd layer as bonding layers.

The diagram particularly illustrates the bonding energy for two different post-bonding treatments, at 600° C. and 800° C. For both cases, the bonding energy between a silicon nitride layer and a BPSGd layer is higher than between two BPSGd layers. With a treatment at 800° C., the bonding energy between the silicon nitride layer and the BPSGd layer can even be further increased.

After the separation or splitting step for transferring part of the seed substrate, a first layered structure 19 and a second layered structure 21, as shown in FIG. 8, are obtained. The method of transferring the semiconductor layer 3 to the first layered structure 19 is usually referred to as Smart Cut™ process, the general conditions of which are well known in the art. Compared with prior art methods, the inventive method described herein can reduce the number of cracks and non-transferred regions.

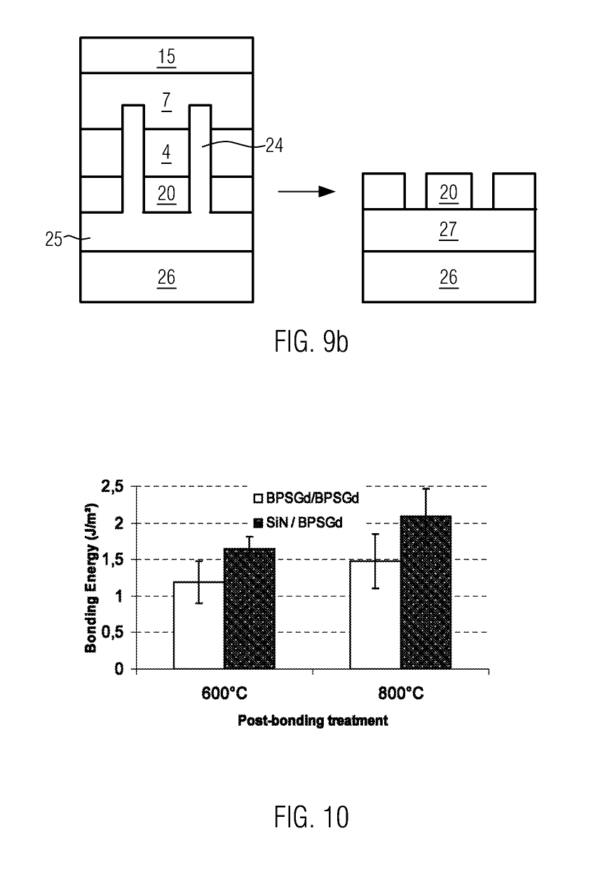

Subsequently, the transferred seed layer 23 can possibly be removed and trenches 24 may be formed in the transferred semiconductor layer 3, the bonding layer 4 and at least partly in the bonding layer 7. Such a structure is shown in FIG. 9a. In this way, an island shaped transferred semiconductor layer may be formed.

Next, relaxation of the island shaped transferred semiconductor layer may be performed as described in the US published patent application 2011/0180911. In particular, the relaxation may comprise a sequence of controlled heat treatments and/or etchings of the transferred seed layer 23, if this layer 23 has been preserved. In particular, a relaxed atomic lattice spacing may be obtained for the transferred semiconductor layer 3, which, in this example, may consist of InGaN.

Subsequently, a silicon oxide layer 25 may be formed in particular using PECVD, filling the trenches 24 and covering the island shaped transferred semiconductor layer. As shown in FIG. 9a, this silicon oxide layer 25 may be bonded to a target substrate 26. The target substrate 26 may comprise or consist of a target support layer of sapphire or silicon and may be cleaned before bonding to the silicon oxide layer 25. The silicon oxide layer 25 may particularly comprise or consist of silicon dioxide and may have to be polished.

Subsequently, the handle support layer 6 may be removed using a laser lift off method as disclosed in patent application WO 2010/015878 without damaging the handle support layer 6. In this way, an intermediate layered structure as shown in FIG. 9b may be obtained.

The intermediate layered structure may then be processed by etching and/or polishing to obtain the final product shown on the right hand side of FIG. 9b. The final product comprises a target substrate 26, a remaining silicon oxide layer 27 remaining from the silicon oxide layer 25 and an island shaped transferred semiconductor layer.

In the final product obtained by a method as described above, the number of defects can be significantly decreased.

Although the previously discussed embodiments and examples of the present invention have been described separately, it is to be understood that some or all of the above described features can also be combined in different ways. The discussed embodiments are not intended as limitations but serve as examples illustrating features and advantages of the invention. Also, all patent applications cited herein are expressly incorporated herein by reference thereto.

What is claimed is:

1. A method for manufacturing a semiconductor substrate, which comprises:
providing a seed support layer and a handle support layer;
providing a strained semiconductor layer over the seed support layer;
providing a bonding layer upon the strained semiconductor layer;
providing a bonding layer upon the handle support layer; and
directly bonding the bonding layers together to obtain a donor-handle compound comprising the seed support layer bonded to the handle support layer;
wherein one of the bonding layers comprises a silicon, nitride in order to enhance bonding strength between the seed support layer and the handle support layer.

2. The method according to claim 1, wherein the other one of the bonding layers comprises a silicon oxide.

3. The method according to claim 2, wherein the bonding layer comprising a silicon nitride comprises or consists of SiN Material or SiₓN_{y}:H and wherein the bonding layer comprising silicon oxide comprises or consists of borophosphosilicate glass or plasma enhanced chemical vapor deposition oxide.

4. The method according to claim 1, which further comprises providing a seed layer upon the seed support layer and forming the semiconductor layer by pseudomorphic epitaxy upon the seed layer.

5. The method according to claim 4, wherein the semiconductor layer is provided in a strained state by providing the seed layer with an atomic lattice spacing which does not match the atomic lattice spacing of the semiconductor layer.

6. The method according to claim 1, wherein the bonding layer comprising a silicon nitride is formed by plasma enhanced chemical vapor deposition or by low pressure chemical vapor deposition, and the semiconductor layer comprises a Group III-V semiconductor material.

7. The method according to claim 1, which further comprises providing a low viscosity compliant layer upon the seed support layer or handle support layer before providing the bonding layer comprising a silicon nitride thereon.

8. The method according to claim 7, which further comprises subjecting the bonding layer comprising silicon-nitride or the compliant layer to a thermal treatment before the bonding step.

9. The method according to claim 1, wherein the handle support layer comprises or consists of sapphire, and the method further comprises forming an absorbing layer between the handle support layer and its respective bonding layer.

10. The method according to claim 1, which further comprises processing each of the bonding layers to reduce its respective surface roughness to less than 5 Angstroms before the bonding step.

11. The method according to claim 1, which further comprises implanting ionic species through the semiconductor layer to form a weakened plane at a depth h inside the seed substrate prior to bonding, and, after bonding, transferring the semiconductor layer to the donor-handle compound by separation at the predetermined weakened plane.

12. The method according to claim 11, which further comprises forming trenches in the transferred semiconductor layer to obtain island shaped structures in the transferred semiconductor layer.

13. The method according to claim 12, which further comprises providing a low viscosity compliant layer upon the handle support layer before providing the bonding layer thereon, and forming the trenches at least partly into the compliant layer.

14. The method according to claim 13, which further comprises at least partially relaxing the transferred semiconductor layer by applying a heat treatment to the donor-handle compound.

15. The method according to claim 11, which further comprises bonding the transferred semiconductor layer and donor-handle compound to a target substrate, followed by detaching the handle support layer by laser lift off.

16. The method according to claim 11, wherein the weakened plane is formed in the seed layer of the seed substrate, and which further comprises transferring at least a part of the seed layer to the handle support layer, thereby forming a transferred seed layer over the transferred semiconductor layer.

17. The method according to claim 16, wherein the handle support layer, the seed support layer and the target substrate comprise or consist of sapphire, the seed layer comprises or consists of GaN and the strained semiconductor layer comprises or consists of InGaN.

18. A donor-handle compound comprising:
a seed substrate comprising a seed support layer, a strained semiconductor layer upon the seed support layer, and a first bonding layer, the seed substrate including a weakened plane therein; and
a handle substrate comprising a handle support layer and a second bonding layer;
wherein a direct bonding is provided between the first and second bonding layers, and
wherein one of the first or second bonding layers comprises a silicon nitride.

19. The donor-handle compound according to claim 18, wherein the other one of the first or second bonding layers comprises or consists of a silicon oxide.

20. A layered structure comprising a handle support layer and a strained material layer; wherein the strained material layer is bonded to the handle support layer via a first bonding layer comprising a silicon nitride and a second bonding layer comprising a silicon oxide.

21. The layered structure according to claim 20, further comprising trenches in at least the strained material layer and optionally also in the first bonding layer, the second bonding layer, or both bonding layers.

22. The layered structure according to claim 20, further comprising an absorbing layer provided between the handle support layer and the first and second bonding layers.
